(19) United States
(12) Patent Application Publication
(10) Pub. No.: US 2020/0303221 A1
(43) Pub. Date: Sep. 24, 2020

(54) SEMICONDUCTOR DEVICE MANUFACTURING METHOD

(71) Applicants: Kabushiki Kaisha Toshiba, Tokyo (JP); Toshiba Electronic Devices & Storage Corporation, Tokyo (JP)

(72) Inventors: Masaru Hatano, Oita Oita (JP); Kazuyuki Fukuyama, Oita Oita (JP)

(21) Appl. No.: 16/562,526

(22) Filed: Sep. 6, 2019

(30) Foreign Application Priority Data
Mar. 20, 2019 (JP) 2019-052616

(51) Int. Cl. H01L 21/67; H01L 21/3065; H01L 21/762; H01J 37/32

(52) U.S. Cl. CPC H01L 21/67069; H01L 21/3065; H01J 2237/3341; H01J 37/321; H01L 21/76224

(57) ABSTRACT

A semiconductor device manufacturing method according to the embodiment uses a reactive ion etching apparatus configured to etch a sample mounted on a holder, the apparatus use a plasma generated by applying a first high-frequency wave having a first power to an induction coil, the apparatus apply the holder a second high-frequency wave having a second power. The method includes forming an insulating film on a semiconductor substrate; patterning the insulating film; and forming a trench in the semiconductor substrate using the apparatus with the insulating film as a mask. The forming the trench includes first and second etching step, the second power in the first etching step is set to 20% or more and 40% or less of the first power, and the second power in the second etching step is set to 3% or more and 30% or less of the second power in the first etching step.

### CROSS-REFERENCE TO RELATED APPLICATION

This application is based upon and claims the benefit of priority from Japanese Patent Application No. 2019-052616, filed on Mar. 20, 2019, the entire contents of which are incorporated herein by reference.

### FIELD

Embodiments described herein relate generally to a semiconductor device manufacturing method.

### BACKGROUND

An element isolation region is formed to electrically isolate elements formed in a semiconductor substrate. As one of element isolation regions, there is a shallow trench isolation (STI) structure in which an insulating film is buried in a trench formed in a semiconductor substrate. The concentration of electric field at a bottom corner of the trench forming the STI structure causes degradation in device characteristics and device reliability.

### BRIEF DESCRIPTION OF THE DRAWINGS

FIG. 1 is a schematic view of an example of an RIE apparatus used in a semiconductor device manufacturing method according to an embodiment;

FIG. 2 is a schematic sectional view showing the semiconductor device manufacturing method according to the embodiment;

FIG. 3 is a schematic sectional view showing the semiconductor device manufacturing method according to the embodiment;

FIG. 4 is a schematic sectional view showing the semiconductor device manufacturing method according to the embodiment;

FIG. 5 is an explanatory view of the function and effect of the semiconductor device manufacturing method according to the embodiment; and

FIGS. 6A, 6B, and 6C are explanatory views of the function and effect of the semiconductor device manufacturing method according to the embodiment.

### DETAILED DESCRIPTION

A semiconductor device manufacturing method according to one aspect of the present invention is a semiconductor device manufacturing method using a reactive ion etching apparatus configured to etch a sample mounted on a holder, the reactive ion etching apparatus configured to use a plasma generated by applying a first high-frequency wave having a first power to an induction coil, the reactive ion etching apparatus configured to apply the holder a second high-frequency wave having a second power, the method comprising: forming an insulating film on a semiconductor substrate; patterning the insulating film; and forming a trench in the semiconductor substrate using the reactive ion etching apparatus with the insulating film as a mask, the forming the trench including a first etching step and a second etching step successively performed after the first etching step, the second power in the first etching step being set to 20% or more and 40% or less of the first power, and the second power in the second etching step being set to 3% or more and 30% or less of the second power in the first etching step.

In this specification, the same or similar members will be denoted by the same reference symbols, and redundant descriptions are omitted sometimes.

In this specification, the upper direction of the drawing is sometimes described as “on” and the lower direction of the drawing as “under” to indicate the positional relationship between parts and the like. In the specification, the terms “on” and “under” are not necessarily terms indicating the relationship with the direction of gravity.

A semiconductor device manufacturing method according to an embodiment is a semiconductor device manufacturing method using a reactive ion etching apparatus configured to etch a sample mounted on a holder. The reactive ion etching apparatus configured to use plasma generated by applying a first high-frequency wave having a first power to an induction coil, the reactive ion etching apparatus configured to apply the holder a second high-frequency wave having a second power. The method includes forming an insulating film on a semiconductor substrate, patterning the insulating film, and forming a trench in the semiconductor substrate using the reactive ion etching apparatus with the insulating film as a mask. The forming the trench includes a first etching step and a second etching step successively performed after the first etching step. The second power in the first etching step is set to 20% or more and 40% or less of the first power, and the second power in the second etching step is set to 3% or more and 30% or less of the second power in the first etching step.

The semiconductor device manufacturing method according to the embodiment is a method of manufacturing a semiconductor device including an element isolation region having an STI structure. A semiconductor device manufacturing method according to the embodiment uses a reactive ion etching (RIE) apparatus using an inductively coupled plasma (ICP) to form a trench having an STI structure.

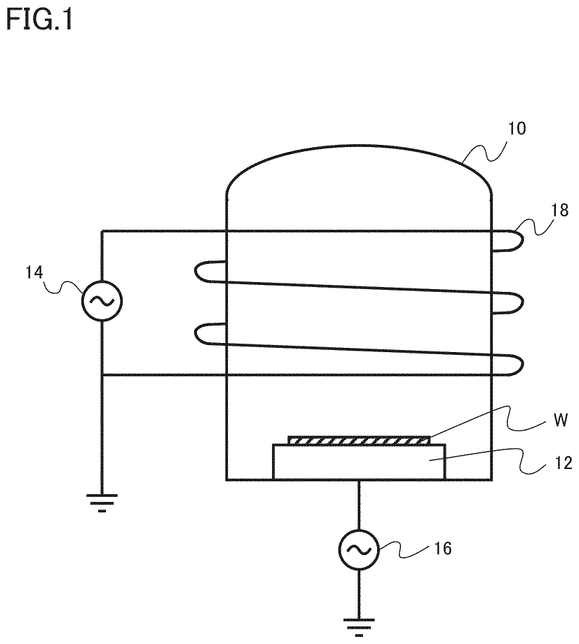

FIG. 1 is a schematic view of an example of an RIE apparatus used in the semiconductor device manufacturing method according to the embodiment. The RIE apparatus etches a sample using an inductively coupled plasma.

The RIE apparatus includes a dielectric chamber 10, a holder 12, a source power supply 14, a bias power supply 16, and an induction coil 18.

The holder 12 is provided in the dielectric chamber 10. The holder 12 mounts, for example, a semiconductor substrate W (sample). The holder 12 is, for example, an electrostatic chuck.

The source power supply 14 has a function of applying a first high-frequency wave having a source power (first power) to the induction coil 18. The first high-frequency wave having a source power is applied to the induction coil 18 to generate a plasma in the dielectric chamber 10.

The bias power supply 16 has a function of applying a second high-frequency wave having a bias power (second power) to the holder 12.

The semiconductor substrate W mounted on the holder 12 is anisotropically etched using the plasma generated in the dielectric chamber 10.

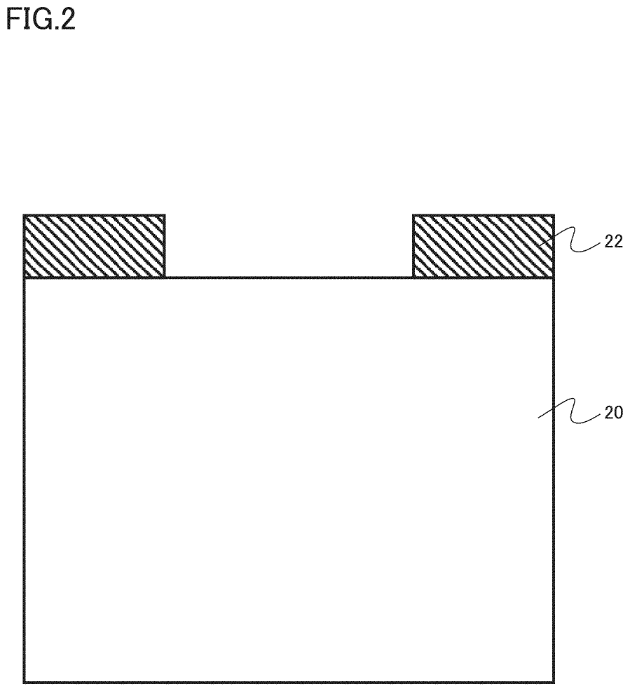

FIGS. 2, 3, and 4 are schematic sectional views showing the semiconductor device manufacturing method according to the embodiment.

First of all, a single crystal silicon substrate 20 is prepared. The single crystal silicon substrate 20 is an example of a semiconductor substrate.

A silicon nitride film 22 is deposited on the surface of the single crystal silicon substrate 20. The silicon nitride film 22 is an example of an insulating film. Note that, for example, a stacked film of a silicon nitride film and a silicon oxide film can be used as an insulating film.

The silicon nitride film 22 is deposited by, for example, a chemical vapor deposition method (CVD method). The film thickness of the silicon nitride film 22 is, for example, 100 nm or more and 1000 nm or less.

The silicon nitride film 22 is then patterned (FIG. 2). The silicon nitride film 22 is patterned using, for example, a lithography method and an RIE method.

Next, a trench 24 is formed in the single crystal silicon substrate 20 using the patterned silicon nitride film 22 as a mask. The trench 24 is formed by using an RIE apparatus using an inductively coupled plasma shown in FIG. 1.

In the forming the trench 24, a first etching step and a second etching step which is successively performed after the first etching step are performed.

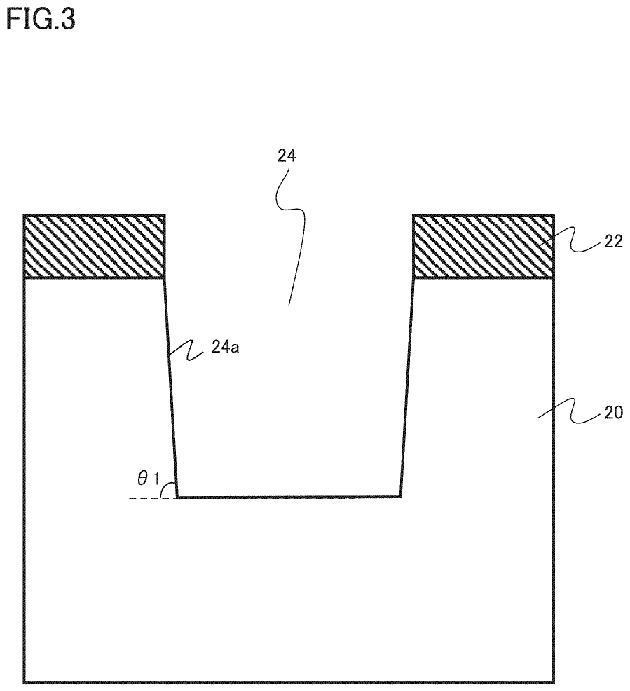

In the first etching step, the etching is stopped before reaching the target depth of the trench 24 (FIG. 3). For example, the etching is stopped at a depth of 75% or more and 95% or less of the target depth of the trench 24.

The first etching step forms an upper side surface 24a of the trench 24. The first taper angle (θ1 in FIG. 3) of the upper side surface 24a is, for example, 75° or more and 90° or less.

In the first etching step, the bias power is set to 20% or more and 40% or less of the source power. The source power in the first etching step is, for example, 400 W or more and 800 W or less. The bias power in the first etching step is, for example, 150 W or more and 250 W or less.

The temperature of the holder 12 in the first etching step is, for example, 40° C. or more and 60° C. or less.

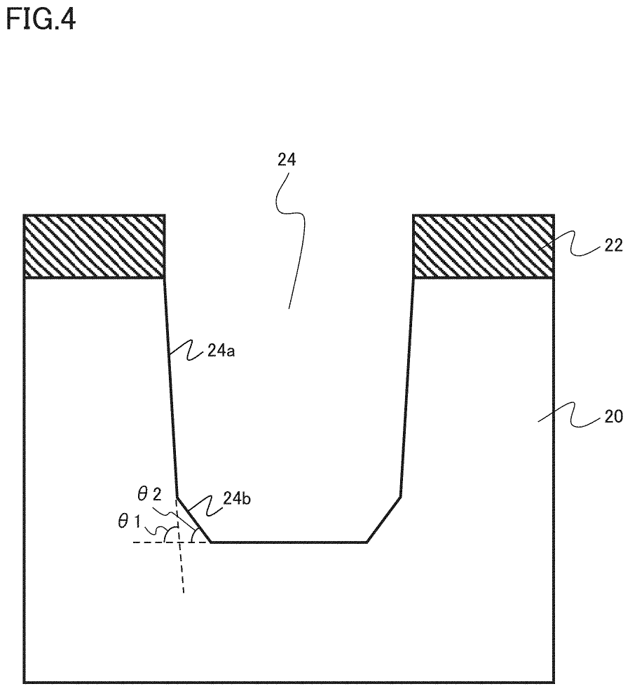

In the second etching step, etching is performed until it reaches the target depth of the trench 24 (FIG. 4). The second etching step forms a lower side surface 24b of the trench 24. The second taper angle (θ2 in FIG. 4) of the lower side surface 24b is smaller than the first taper angle θ1 of the upper side surface 24a. The second taper angle θ2 of the lower side surface 24b is, for example, 60° or more and less than 75°.

In the second etching step, the bias power is set to 20% or more and 40% or less of the source power. The source power in the second etching step is, for example, 400 W or more and 800 W or less.

The bias power in the second etching step is set to 3% or more and 30% or less of the bias power in the first etching step. The bias power in the second etching step is, for example, 10 W or more and 50 W or less.

The target depth of the trench 24 is, for example, 200 nm or more and 500 nm or less.

After the formation of the trench 24, an insulating film is buried in the trench 24. The insulating film is, for example, silicon oxide.

The function and effect of the semiconductor device manufacturing method according to the embodiment will be described next.

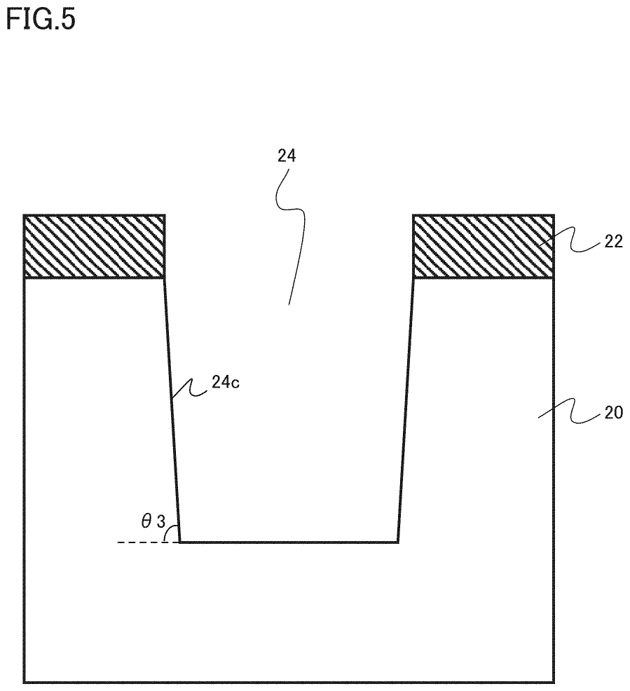

FIG. 5 is an explanatory view of the function and effect of the semiconductor device manufacturing method according to the embodiment. FIG. 5 shows a trench shape when the trench 24 is formed by etching without the second etching step. That is, unlike the embodiment, FIG. 5 shows the shape obtained by performing etching to the target depth of the trench 24 under only the etching conditions corresponding to the first etching step.

The taper angle (83 in FIG. 5) of a side surface 24c of the trench 24 is, for example, 75° or more and 90° or less.

When the taper angle 83 of the side surface 24c of the trench 24 is large, an electric field concentrates at a corner portion of the bottom of the trench 24. Therefore, for example, when a current flows through the corner portion of the trench 24, carriers are trapped in the insulating film, in which the trench 24 is buried, by impact ionization. The trapped carriers cause degradation of device characteristics and reliability.

In the semiconductor device manufacturing method according to the embodiment, the step of forming the trench 24 includes the first etching step and the second etching step performed successively after the first etching step. In the second etching step, the bias power is reduced lower than that in the first etching step. Accordingly, the second taper angle θ2 of the lower side surface 24b of the trench 24 is smaller than the first taper angle 91 of the upper side surface 24a of the trench 24. This suppresses the concentration of an electric field at the corner portion of the bottom of trench 24. Therefore, the degradation of the characteristics and reliability of the device having the STI structure is suppressed.

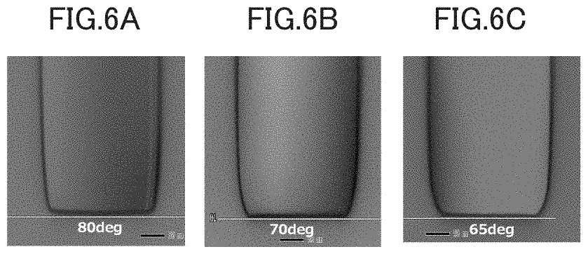

FIGS. 6A, 6B, and 6C are explanatory views of the function and effect of the semiconductor device manufacturing method according to the embodiment. FIGS. 6A, 6B, and 6C each are a scanning electron micrograph showing the sectional shape of the trench 24 immediately after etching. FIG. 6A shows a case in which the second etching step is not performed, and FIGS. 6B and 6C each show a case in which the second etching step is performed.

FIG. 6B shows a case in which the bias power in the second etching step is set to 25% of that in the first etching step, and FIG. 6C shows a case in which the bias power in the second etching step is set to 5% of that in the first etching step.

The bias power in the first etching step was 200 W. The source power in the first etching step and the second etching step was 600 W.

As shown in FIG. 6A, the taper angle of the side surface of the trench 24 when the second etching step is not performed is almost constant at 800. When the second etching step is performed, for example, as shown in FIG. 6B, the taper angle of the upper side surface 24a is 80°, and the taper angle of the lower side surface 24b is 70°, which is smaller than that of the upper side surface 24a. In addition, when the bias power in the second etching step is further lowered, as shown in FIG. 6C, the taper angle of the upper side surface 24a is 80°, and the taper angle of the lower side surface 24b is 65°. That is, the taper angle of the lower side surface 24b becomes smaller.

Note that the taper angle of the upper side surface 24a is the taper angle of the tangent of the side surface of the trench 24 at a position higher by a distance ½ of the depth of the trench from the bottom of the trench. The taper angle of the lower side surface 24b is the taper angle of the tangent of the side surface of the trench 24 at a position higher by a distance 1/20 of the depth of the trench from the bottom of the trench.

In the semiconductor device manufacturing method according to the embodiment, the bias power is set to 20% or more and 40% or less of the source power. With this setting, it is possible to stably form the taper angle of the upper side surface 24a and the taper angle of the lower side surface 24b at desired values.

The source power is preferably 400 W or more and 800 W or less, more preferably 500 W or more and 700 W or less, from the viewpoint of stably forming the taper angle of the upper side surface 24a and the taper angle of the lower side surface 24b at desired values.

The first taper angle θ1 is preferably 75° or more and 90° or less. If the first taper angle is below the above range, the width of the trench 24 becomes large, resulting in difficulty in scaling down the device. If the first taper angle is above the above range, it becomes difficult to bury the insulating film in the trench 24.

The bias power in the first etching step is preferably 150 W or more and 250 W or less. Setting the above range makes it easy to control the first taper angle θ1 to 75° or more and 90° or less.

The second taper angle θ2 is preferably 60° or more and less than 75°. If the second taper angle is below the above range, the electric field concentration at the corners between the upper side surface 24a and the lower side surface 24b may increase. If the second taper angle is above the above range, the suppression of the electric field concentration at a corner portion of the bottom of the trench 24 may be insufficient.

The bias power in the second etching step is 3% or more and 30% or less of the bias power in the first etching step. The bias power in the second etching step is preferably 5% or more and 25% or less of the bias power in the first etching step. The bias power in the second etching step is preferably 10 W or more and 50 W or less. Setting the above range makes it easy to control the second taper angle θ2 to 60° or more and less than 75°.

Moreover, it is preferable to set temperature of the holder 12 to 40° C. or more and 60° C. or less. Etching the trench 24 in the above temperature range makes it possible to stably form the taper angle of the upper side surface 24a and the taper angle of the lower side surface 24b at desired values.

Furthermore, after the second etching step, it is also possible to perform a third etching step which is performed successively after the second etching step. In the third etching step, the bias power is set to be smaller than the bias power in the second etching step. Providing the third etching step makes it possible to change the taper angle of the side surface of the trench 24 stepwise and suppress the electric field concentration at the corner portion of the bottom of the trench 24.

While certain embodiments have been described, these embodiments have been presented by way of example only, and are not intended to limit the scope of the inventions. Indeed, a semiconductor device manufacturing method described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device manufacturing method using a reactive ion etching apparatus configured to etch a sample mounted on a holder, the reactive ion etching apparatus configured to use a plasma generated by applying a first high-frequency wave having a first power to an induction coil, the reactive ion etching apparatus configured to apply the holder a second high-frequency wave having a second power, the method comprising:
forming an insulating film on a semiconductor substrate;
patterning the insulating film; and
forming a trench in the semiconductor substrate using the reactive ion etching apparatus with the insulating film as a mask, the forming the trench including a first etching step and a second etching step successively performed after the first etching step, the second power in the first etching step being set to 20% or more and 40% or less of the first power, and the second power in the second etching step being set to 3% or more and 30% or less of the second power in the first etching step.

2. The semiconductor device manufacturing method according to claim 1, wherein in the forming the trench, a temperature of the holder is set to 40° C. or more and 60° C. or less.

3. The semiconductor device manufacturing method according to claim 1, wherein the first power in the forming the trench is 400 W or more and 800 W or less.

4. The semiconductor device manufacturing method according to claim 1, wherein the second power in the first etching step is 150 W or more and 250 W or less, and the second power in the second etching step is 10 W or more and 50 W or less.

5. The semiconductor device manufacturing method according to claim 1, wherein the forming the trench includes a third etching step performed successively after the second etching step, and the second power in the third etching step is smaller than the second power in the second etching step.

6. A semiconductor device manufacturing method using a reactive ion etching apparatus configured to etch a sample mounted on a holder, the reactive ion etching apparatus configured to use a plasma generated by applying a first high-frequency wave having a first power to an induction coil, the reactive ion etching apparatus configured to apply the holder a second high-frequency wave having a second power, the method comprising:
forming an insulating film on a silicon substrate;
patterning the insulating film; and
forming a trench in the silicon substrate using the reactive ion etching apparatus with the insulating film as a mask, the forming the trench including a first etching step and a second etching step successively performed after the first etching step, the second power in the first etching step being set to 20% or more and 40% or less of the first power, and the second power in the second etching step being set to 3% or more and 30% or less of the second power in the first etching step.

7. The semiconductor device manufacturing method according to claim 6, wherein the first power in the forming the trench is 400 W or more and 800 W or less.

8. The semiconductor device manufacturing method according to claim 7, wherein the second power in the first etching step is 150 W or more and 250 W or less, and the second power in the second etching step is 10 W or more and 50 W or less.

9. The semiconductor device manufacturing method according to claim 6, wherein the forming the trench includes a third etching step performed successively after the second etching step, and the second power in the third etching step is smaller than the second power in the second etching step.

10. A semiconductor device manufacturing method using a reactive ion etching apparatus configured to etch a sample mounted on a holder, the reactive ion etching apparatus configured to use a plasma generated by applying a first high-frequency wave having a first power to an induction coil, the reactive ion etching apparatus configured to apply the holder a second high-frequency wave having a second power, the method comprising:
forming an insulating film on a semiconductor substrate;
patterning the insulating film;
forming a trench in the semiconductor substrate using the reactive ion etching apparatus with the insulating film as a mask, the forming the trench including a first etching step and a second etching step successively performed after the first etching step, the second power in the first etching step being set to 20% or more and 40% or less of the first power, and the second power in the second etching step being set to 3% or more and 30% or less of the second power in the first etching step; and
burying an insulating film in the trench after the forming the trench.

11. The semiconductor device manufacturing method according to claim 10, wherein the insulating film is silicon oxide.

12. The semiconductor device manufacturing method according to claim 10, wherein in the forming the trench, a temperature of the holder is set to 40° C. or more and 60° C. or less.

13. The semiconductor device manufacturing method according to claim 10, wherein the first power in the forming the trench is 400 W or more and 800 W or less.

14. The semiconductor device manufacturing method according to claim 10, wherein the second power in the first etching step is 150 W or more and 250 W or less, and the second power in the second etching step is 10 W or more and 50 W or less.
